(19) United States
(12) Patent Application Publication
(10) Pub. No.: US 2026/0169043 A1
(43) Pub. Date: Jun. 18, 2026

(54) DISTRIBUTION GRID AWARENESS

(71) Applicant: Analog Devices International Unlimited Company, Limerick (IE)

(72) Inventors: Michael R. PRICE, Medford, MA (US); Xiao Yu WANG, Watertown, MA (US); Frank YAUL, Somerville, MA (US); Alan O'CONNOR, Dedham, MA (US); Atulya YELLEPEDDI, Medford, MA (US); Cecelia CHU, Cambridge, MA (US); Matthew BEGG, Boston, MA (US); William HOLLAND, Edinburgh (GB); Boris LERNER, Sharon, MA (US); Pranav KULKARNI, Pasadena, CA (US)

(21) Appl. No.: 19/419,608

(22) Filed: Dec. 15, 2025

Related U.S. Application Data
(63) Continuation-in-part of application No. 19/410,480, filed on Dec. 5, 2025.
(60) Provisional application No. 63/734,672, filed on Dec. 16, 2024.
(60) Provisional application No. 63/929,375, filed on Dec. 2, 2025.

(51) Int. Cl. G01R 27/16; H02J 3/38; H02J 13/12; H02J 103/30

(52) U.S. Cl. CPC G01R 27/16; H02J 3/38; H02J 13/12; H02J 2103/30

(57) ABSTRACT

The technology may inject, at one or more stimulus source nodes, an active small-signal electrical stimulus. The technology may detect stimulus-correlated responses at a plurality of measurement nodes of the network. The technology may estimate at least one model parameter indicative of the network structure or impedance based at least in part on the detected stimulus-correlated responses.

### CROSS REFERENCE TO RELATED APPLICATIONS

This application is a continuation-in-part of U.S. patent application Ser. No. 19/410,480, filed Dec. 5, 2025, titled “Electrical Power Network Topology Mapping,” the entire contents of which are incorporated by reference herein. This application also claims the benefit of U.S. Provisional Ser. No. 63/734,672 , filed Dec. 16, 2024, titled “Methods to Enable Visibility Across the Distribution Grid,” and U.S. Provisional Ser. No. 63/929,375 , filed Dec. 2, 2025, titled “Awareness, Modeling, and Control of Distribution-Grid Characteristics,” the entire contents of each of which are incorporated by reference herein.

### FIELD OF THE DISCLOSURE

The present disclosure relates to electrical power distribution systems. Examples relate particularly to systems and methods for sensing, modeling, and estimating distribution-grid characteristics using synchronized and unsynchronized electrical measurements, active and passive stimulus, and software algorithms executed on distributed and centralized computing resources.

### BACKGROUND

An alternating-current distribution network can be represented as a set of interconnected nodes linked by conductors and transformers. Each customer premise typically connects to a secondary distribution transformer; the point where a device or premise ties into the network is often called the point of common coupling. In multi-phase systems, loads and sources may connect to one or more phases, and phase association influences how voltages and currents appear at different locations in the network.

Electrical impedance is the complex ratio of voltage to current at a given frequency. In sinusoidal steady-state analysis, voltages and currents are often expressed as phasors so that impedance has both magnitude and phase. Power-system analysis frequently employs reference nodes and grounding conventions as conceptual aids for comparing quantities measured at different points in a network.

Distributed energy resources (DERs) and controllable loads, such as photovoltaic inverters, energy storage inverters, and electric vehicle supply equipment (EVSE), are grid-connected power electronic devices that can source or sink power and that often provide electrical measurements or telemetry. Metering infrastructure, including utility meters, sub-meters, and sensors co-located with grid equipment, can provide nodal measurements of electrical quantities such as voltage and, in some cases, current. In the frequency domain, analysis techniques including Fourier transforms and filtering are widely used to characterize periodic components in electrical signals.

Because measured electrical quantities can be complex-valued, both magnitude and phase convey information about relationships among nodes, including phase association. Graph representations are commonly used to describe network connectivity, with nodes representing connection points and edges representing conductors or transformer links; impedances and phase associations can be treated as attributes on nodes and edges. Finally, electrical compatibility considerations address how various signal components coexist with line frequency and harmonics. Power-line communications is a general term for transmitting information over power conductors, typically at higher frequencies, and is distinct from normal operational variations of electrical power in distribution systems.

### SUMMARY OF THE DISCLOSURE

In some aspects, the techniques described herein relate to a method for modeling an electrical distribution network spanning low-voltage (LV) and medium-voltage (MV) portions, including: injecting, at one or more stimulus source nodes, an active small-signal electrical stimulus; detecting stimulus-correlated responses at a plurality of measurement nodes of the network and estimating at least one model parameter indicative of the network structure or impedance based at least in part on the detected stimulus-correlated responses.

In some aspects, the techniques described herein relate to a method, wherein the at least one model parameter includes an ancestry relationship between one or more stimulus source nodes and one or more measurement nodes.

In some aspects, the techniques described herein relate to a method, wherein the at least one model parameter includes a common impedance between one or more stimulus source nodes and one or more measurement nodes along one or more shared conductor paths.

In some aspects, the techniques described herein relate to a method, wherein detecting stimulus-correlated responses includes detecting, with voltage sensors at a plurality of nodes, stimulus-correlated voltage responses; and wherein estimating the at least one model parameter includes estimating common impedance without requiring a current measurement at the one or more stimulus source nodes.

In some aspects, the techniques described herein relate to a method, wherein detecting stimulus-correlated responses includes detecting, with one or more MV current sensors positioned upstream of a distribution transformer, stimulus-correlated current responses, and the estimating includes determining at least one of upstream-downstream ancestry relationships and transformer parameters between LV and MV assets.

In some aspects, the techniques described herein relate to a method, further including combining the at least one model parameter with passively acquired voltage or current measurements from LV or MV sensors to produce a network model including topology and one or more line parameters.

In some aspects, the techniques described herein relate to a method, wherein the passively acquired measurements are time-synchronized or unsynchronized.

In some aspects, the techniques described herein relate to a method, wherein injecting and detecting are time-synchronized across nodes using distributed time synchronization, and optionally using the stimulus to facilitate synchronization.

In some aspects, the techniques described herein relate to a method, further including performing network model estimation or correction using priors including at least one of geospatial topology, known switch locations, or distance constraints, and accepting hypotheses according to one or more residual metrics.

In some aspects, the techniques described herein relate to a method, further including compensating for interference or leakage currents using statistical or simulation-based correction to improve accuracy of impedance- and transfer-gain-based estimates.

In some aspects, the techniques described herein relate to a method, further including obtaining power-line channel measurements at frequencies distinct from line frequency and using corresponding channel impulse response characteristics to constrain topology hypotheses.

In some aspects, the techniques described herein relate to a method, wherein the active small-signal electrical stimulus is patterned to permit concurrent multi-node sensing without net energy bias and is generated by one or more distributed energy resources.

In some aspects, the techniques described herein relate to a method, further including executing state estimation over the modeled network, and partitioning computation between edge algorithmic collector nodes that produce local estimates and reduced data products, and a cloud service that performs aggregation and refinement.

In some aspects, the techniques described herein relate to a system including: one or more LV voltage sensors, one or more MV current sensors, and one or more stimulus injectors; and one or more processors configured to: issue control signals to inject an active small-signal electrical stimulus at one or more stimulus source nodes; receive stimulus-correlated responses detected at a plurality of measurement nodes; and estimate at least one model parameter indicative of the network structure or impedance based at least in part on the detected stimulus-correlated responses.

In some aspects, the techniques described herein relate to a system, wherein the one or more processors are configured to: form, by the one or more processors, a common-impedance matrix Z from electrical measurements at a plurality of nodes; for each pair of nodes in an active set, compute, under a probabilistic model, likelihoods of relationship states selected from unrelated, parent-child, and siblings based on entries of Z; enforce global relationship-consistency constraints including at least acyclicity of parent-child links, common parentage of sibling cliques, and transitivity of sibling grouping; select relationships according to posterior probabilities to form sibling cliques and parent-child connections, inferring hidden parent nodes for sibling cliques, and updating the active set by removing nodes whose parents have been determined and adding inferred hidden parents; pool repeated observations of a same underlying common impedance across entries of Z to reduce variance; and iteratively repeat the computing, enforcing, selecting, inferring, updating, and pooling until a tree topology with hidden nodes and branch impedances is produced, wherein the computing, enforcing, selecting, inferring, updating, and pooling operate directly on the common-impedance matrix Z rather than on an effective-impedance matrix, and optionally employing beam search or hypothesis pruning to manage candidate relationship sets.

In some aspects, the techniques described herein relate to a non-transitory computer-readable medium storing instructions that, when executed by one or more processors, cause the one or more processors to perform operations including: issuing control signals to inject an active small-signal electrical stimulus at one or more LV stimulus source nodes; receiving stimulus-correlated responses detected at a plurality of measurement nodes; and estimating at least one model parameter indicative of the network structure or impedance based at least in part on the detected stimulus-correlated responses.

### BRIEF DESCRIPTION OF THE DRAWINGS

The present technology will now be described in more detail with reference to the accompanying drawings, which are not intended to be limiting.

FIG. 1 is a block diagram illustrating an electrical power distribution network spanning medium-voltage (MV) and low-voltage (LV) portions, together with sensing, stimulus injection, synchronization, communications, and processing components configured to estimate network topology and electrical parameters using stimulus correlated responses, in accordance with examples of the technology disclosed herein.

FIG. 2 is a block diagram illustrating relationships between techniques used in the network of FIG. 1, in accordance with examples of the technology disclosed herein.

FIG. 3 is a flow chart of methods of modeling an electrical distribution network is illustrated, in accordance with examples of the technology disclosed herein.

FIG. 4 is a flow chart of methods of modeling an electrical distribution network is illustrated, in accordance with examples of the technology disclosed herein.

FIG. 5 is a flow chart of methods of modeling an electrical distribution network is illustrated, in accordance with examples of the technology disclosed herein.

FIG. 6 is a flow chart of methods of modeling an electrical distribution network is illustrated, in accordance with examples of the technology disclosed herein.

FIG. 7 is a flow chart of methods of modeling an electrical distribution network is illustrated, in accordance with examples of the technology disclosed herein.

FIG. 8 is a flow chart of methods of modeling an electrical distribution network is illustrated, in accordance with examples of the technology disclosed herein.

FIG. 9 schematically illustrates a device that may serve as a computer/processor, in accordance with examples of the technology disclosed herein.

### DETAILED DESCRIPTION

In the following detailed description, reference is made to the accompanying drawings which form a part hereof wherein like numerals designate like parts throughout, and in which is shown by way of illustration examples that may be practiced. It is to be understood that other examples may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described example. Various additional operations may be performed and/or described operations may be omitted in additional examples. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

Various components may be referred to or illustrated herein in the singular (e.g., a “processor,” a “peripheral device,” etc.), but this is simply for ease of discussion, and any element referred to in the singular may include multiple such elements in accordance with the teachings herein. The description uses the phrases “in an example” or “in examples,” which may each refer to one or more of the same or different examples. Furthermore, the terms “comprising,” “including,” “having,” and the like, as used with respect to examples of the present disclosure, are synonymous. As used herein, the term “circuitry” may refer to, be part of, or include an application-specific integrated circuit (ASIC), an electronic circuit, and optical circuit, a processor (shared, dedicated, or group), and/or memory (shared, dedicated, or group) that execute one or more software or firmware programs, a combinational logic circuit, and/or other suitable hardware that provide the described functionality.

Electric power distribution networks are undergoing rapid change due to increasing penetration of DERs, electrification of transportation and heating, and more frequent extreme weather events. These trends increase operational complexity and stress the capacity of legacy infrastructure. Effective planning and operation of distribution grids require accurate, timely knowledge of the network topology and parameters—such as which assets are connected and energized, the phases to which endpoints are connected, and the impedances of lines and transformers. However, existing technologies face limitations in providing comprehensive, high-fidelity visibility at the scale, cost, and latency required for modern distribution operations.

Typical monitoring architectures in transmission systems rely primarily on networks of synchronized phasor measurement units and centralized state estimation. When applied to distribution, this architecture encounters several barriers. First, distribution networks comprise vastly more nodes than transmission, and equipment costs near the grid edge are much lower, making widespread deployment of high-specification sensors economically prohibitive. Second, the communications bandwidth and backhaul required to aggregate synchronized multi-phase measurements from large numbers of nodes impose burdens on existing utility networks; centralized processing of such volumes can also challenge estimator algorithms. Third, many distribution assets are indoors or in urban canyons with limited access to satellite timing, making ubiquitous GPS-based synchronization impractical; achieving precise inter-sensor synchronization without GPS can itself consume scarce communications resources.

Algorithms used for power-flow analysis and state estimation generally assume that network topology and parameters are known and correct. In practice, geographic information system records for distribution networks are often incomplete or inaccurate, particularly at low voltage. Switch states are frequently unmonitored, and ad hoc field reconfigurations, cable splices, and jumper changes may not be reflected promptly in enterprise databases. Moreover, distribution topology is dynamic: fault isolation, restoration, and routine operations change energized connectivity, sometimes leaving only partial or outdated records. Behind-the-meter resources and secondary circuits further complicate model fidelity, as they are rarely captured with sufficient detail for operational applications. Even small, plausible topology errors can materially corrupt inferred line and transformer utilizations and degrade upstream analytics.

Advanced metering infrastructure (AMI) provides valuable telemetry but is insufficient to be the sole resource for grid-wide topology inference and real-time operations. AMI penetration remains incomplete in many jurisdictions; upgrade cycles are long; and AMI measurements are typically not time-synchronized across meters, with update intervals on the order of minutes. These characteristics limit the ability to resolve instantaneous state, phase association, or shared-path relationships, and make AMI alone inadequate for feeder-level observability. Distribution SCADA and advanced distribution management systems provide higher-reliability data but are generally limited to substation and selected medium-voltage points, lack synchronized measurements, and refresh at multi-minute cadences. As a result, neither AMI nor SCADA implementations, by themselves, furnish the synchronized, wide-area state information necessary to support modern control functions on distribution networks.

Prior techniques that passively correlate naturally occurring load variations with measured voltages or currents at endpoints suffer from sparse, uncoordinated datasets dominated by end-user behaviour. Signal-to-noise ratios are low and inconsistent, and slow, system-wide drifts confound attribution. High-frequency, event-driven approaches inspired by non-intrusive load monitoring attempt to detect appliance switching or harmonic signatures, but do not recover connectivity relationships. Methods relying on uncontrolled system transients, scheduled utility switching operations, or other opportunistic switching events provide intermittent observability and scale poorly as the number of endpoints grows. Power-line communication and conductor tagging concepts can aid device identification but generally do not yield low-frequency impedance estimates or unified topology reconstructions.

Existing offerings for phase identification and meter-to-transformer mapping leave medium-voltage connectivity and impedance relationships unresolved. Medium-voltage phase detection requires deployment of relatively expensive sensors, and solutions that address medium voltage (MV) and low voltage (LV) networks separately do not produce unified network models spanning both domains. The absence of unified models complicates feeder-level state estimation, device dispatch, and protection coordination.

Errors in topology and parameter models propagate to operational analytics. State estimation predicated on incorrect connectivity can yield biased voltage and current estimates, misstate line and transformer utilization, and confound anomaly detection. Topology errors also create residual patterns that are difficult to distinguish from bad data, complicating data quality workflows. These effects, in turn, hinder demand response targeting, DER coordination, voltage regulation, and hosting capacity assessments, and can drive unnecessary or mis-timed infrastructure upgrades.

Medium-voltage sensing traditionally relies on instrument transformers. Low-power instrument transformers and other compact sensing technologies promise safety and form-factor benefits but are sensitive to installation practices and environmental conditions, including temperature, humidity, cabling geometry, loading, and electromagnetic interference. These sensitivities complicate reliable deployment at scale and increase lifecycle maintenance costs.

Distribution assets have long lifetimes, and widespread replacement or retrofit to embed sensing can take many years. Labor costs for medium-voltage installations are high, and field access is constrained by safety and outage management. Utilities also report bottlenecks in communications backhaul that limit the feasibility of high-rate, tightly synchronized phasor data streams from large numbers of devices. Collectively, these factors impede timely deployment of dense, tightly synchronized phasor-sensing networks and limit the practical observability achievable with current approaches.

Accordingly, there is a need for methods and systems that can deliver accurate, low-latency, and scalable determination of distribution-network topology, phase association, and electrical parameters across low-and medium-voltage domains, despite sparse or imperfect instrumentation, bandwidth and synchronization constraints, dynamic switching, and incomplete enterprise records. There is a further need for techniques that are robust to field noise and environmental variability, integrate with existing sensing infrastructures, and reduce the propagation of model errors into state estimation and grid control applications.

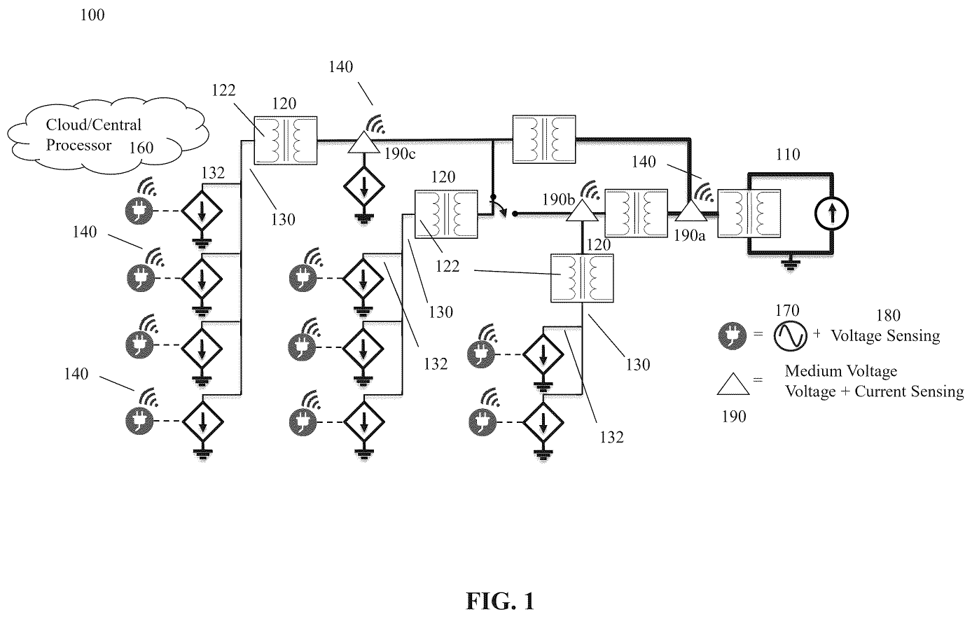

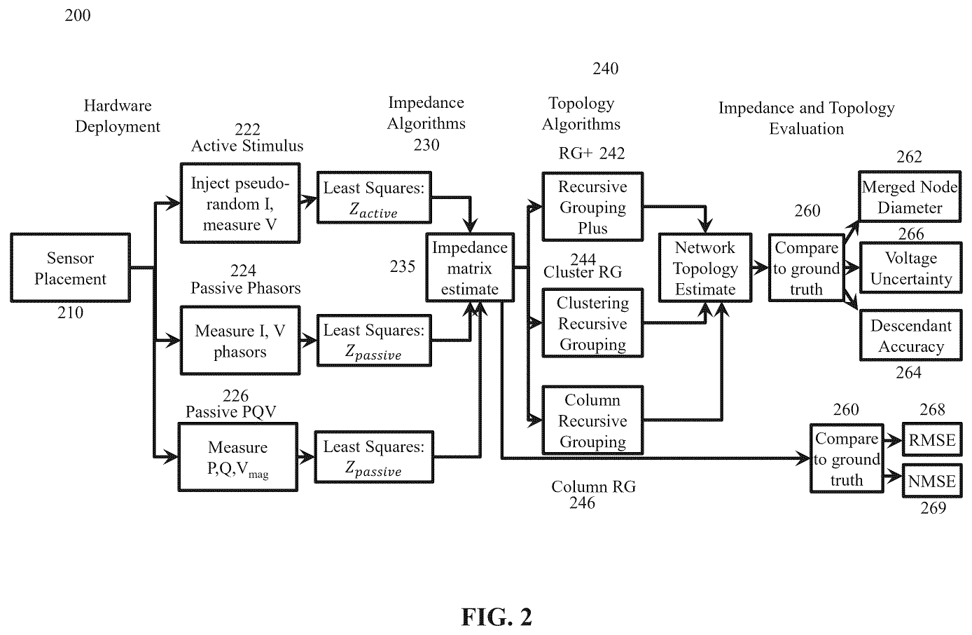

FIG. 1 is a block diagram illustrating an electrical power distribution network 100 spanning medium-voltage (MV) and low-voltage (LV) portions, together with sensing, stimulus injection, synchronization, communications, and processing components configured to estimate network topology and electrical parameters using stimulus-correlated responses, in accordance with examples of the technology disclosed herein. FIG. 2 is a block diagram 200 illustrating relationships between techniques used in network 100, in accordance with examples of the technology disclosed herein.

In the example of FIG. 1, a substation 110 energizes one or more MV feeders that supply MV laterals. MV current sensors 190a, 190b, 190c are installed at selected upstream locations, such as at a feeder head and a midfeeder location according to sensor placement 210. Each MV lateral feeds one or more distribution transformers 120 whose primaries are connected to the MV network and whose secondaries 122 supply LV secondary conductors 130. Service drops 132 couple the LV secondary conductors 130 to customer premises, which include LV nodes such as meter locations and panels. At selected LV nodes, for active stimulus 222 one or more stimulus injectors 170 are operable to inject active small-signal electrical stimuli into the network. The stimulus injectors 170 can be realized in or coupled to distributed energy resources (DERs) such as photovoltaic inverters, battery inverters, and EVSE, or in dedicated wall plug stimulus devices. In addition, or independently, stimulus injectors can be hosted in utility assets including meters, meter collars, and transformer monitors. LV voltage sensors 180 are deployed at a plurality of LV nodes (e.g., within utility meters, submeters, or panel-mounted devices) per sensor placement 210, and may include previously deployed smart meters that supply voltage measurements without hardware modification. In addition, or independently, current sensors can be used at LV nodes, e.g. through placement in a meter collar. MV current sensors 190 acquire stimulus-correlated current responses upstream of distribution transformers 120.

Measurement data and control signals are exchanged over one or more communications networks 140 between field devices and one or more processors 160, e.g., located the cloud. In some examples, one or more edge algorithmic collectors at LV nodes and MV nodes aggregate local sensor data, perform preliminary estimation, and transmit reduced data products to the processor(s) 160 to mitigate backhaul demand. The processor(s) 160 orchestrate stimulus scheduling and synchronization, receive voltage and current measurements, extract stimulus-correlated components, estimate shared-path impedances (e.g., using impedance algorithms 230) and ancestry relationships, fuse active parameters with passive data (such as passive phasors 224 and passive P, Q, V_{mag} data 226), and execute network model estimation and state estimation.

A time-synchronization module, e.g., as part of processor 160, coordinates timing across nodes, optionally leveraging the stimulus, RF, or PLCC signals to assist alignment in GPS-denied environments. Passive data sources (e.g., phasors 224 and P, Q, V_{mag}, sources 226), which may include AMI and SCADA systems, supply additional unsynchronized or time-synchronized voltage, current, or power measurements. Optional power-line channel characterization inputs provide channel responses at frequencies distinct from line frequency to constrain topology hypotheses (e.g., associated with one or more of recursive grouping plus 242, clustering recursive grouping 244, and column recursive grouping 246). Estimated models, parameters, and state are persisted in a model/data store, e.g., in cloud 160, and can be exposed to external applications via an interface.

Stimulus control within the processor(s) 160 selects code patterns and schedules multi-node injections, in some cases with the objective of minimizing energy consumption. For example, the stimulus can have substantially zero-mean real power over the probing interval so that the commanded probe does not consume or deliver net real energy when time-averaged across the observation window. A demodulation and extraction module, e.g., within the cloud/central processors 160, correlates field measurements with the stimulus codebook, producing stimulus-correlated voltage and current responses when active stimulus 222 is used. An impedance/common-path estimator 235, e.g., within the cloud/central processors 160, computes per-node impedances and shared-path metrics, while an ancestry detector infers upstream-downstream relationships across LV and MV domains using LV stimulus and MV current measurements. In some examples, a topology and parameter estimation engine 240 applies priors and constraints. The primary topology-inference method is a recursive grouping-plus (RG+) algorithm operating on the common-impedance matrix Z, which uses probabilistic relationship tests (e.g., unrelated, parent-child, siblings) to select edges, enforce global consistency, infer hidden parent nodes, and iteratively update an active set until a tree is formed. RG+ improves robustness by pooling redundant Z entries that reflect the same underlying common impedance and may use lightweight hypothesis pruning to manage candidate relationships. Separately from RG+, total-least-squares and voltage-power-covariance residual metrics can be employed as alternative topology-estimation approaches and/or as model-evaluation scores for hypothesis comparison, but RG+ does not directly optimize those residuals.

An interference/leakage compensation module mitigates leakage currents, e.g., portions of the stimulus current that travel to other loads or network shunt admittances, instead of being sourced by the substation, and interference to improve accuracy of impedance and transfer-gain estimates. A state estimator operates over the modelled network, optionally partitioning computation between edge collectors and the processor(s) 160.

The example of FIG. 2 can compare the network topology estimate 250 resulting from the topology algorithms 240 to a reference 260 by evaluating the model and state estimated by the disclosed methods against a trusted reference (such as an audited utility model, a controlled testbed configuration, or a high-fidelity simulation) using objective metrics that capture both structural and numerical fidelity. Structural fidelity is assessed by metrics like merged node diameter 262 and descendant accuracy 264. Merged node diameter 262 is the maximum pairwise distance between all estimated nodes that are matched or merged to a single ground truth node, measured either geospatially (meters) or electrically (ohms or per unit); smaller diameters indicate tighter localization. Descendant accuracy 264 measures whether upstream-downstream relationships are recovered correctly: for each reference node (e.g., a transformer or phase), the estimated set of downstream nodes is compared to the true set using set-based scores (e.g., precision, recall, F1, intersection over union), with higher values indicating better ancestry recovery across LV/MV.

Numerical fidelity is assessed by voltage uncertainty 266 together with RMSE 268 and NMSE 269. Voltage uncertainty 266 reflects the estimator's confidence in its voltage outputs (magnitude and/or angle) and is obtained from the state estimator's posterior covariance, optionally including propagated parameter uncertainty; lower uncertainty implies higher operational confidence. RMSE (root mean square error) 268 quantifies absolute error between estimated and true continuous quantities—such as voltages, currents, or impedances—computed as the square root of the mean squared difference, reported in the natural units of the quantity. NMSE (normalized mean square error) 269 scales MSE by a characteristic of the ground truth signal (e.g., variance, squared mean, or a per unit base) to enable comparisons across feeders and conditions; it is unitless and often shown in decibels. In practice, these metrics are computed after applying a consistent matching policy between estimated and ground truth graphs and aligning timestamps for time varying states, and they are reported with aggregate statistics to characterize performance across MV and LV domains.

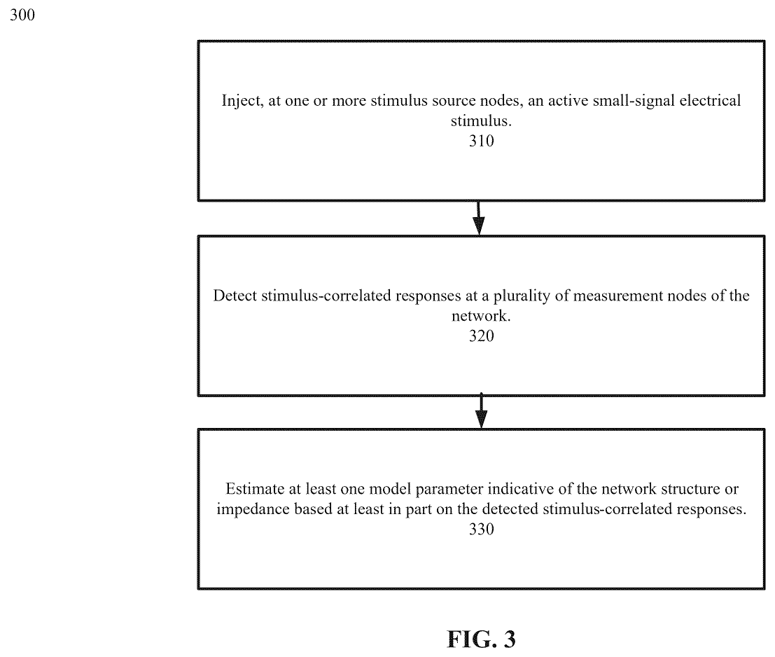

Referring to FIG. 3, and continuing to refer to prior figures for context, a flow chart of methods 300 of modeling an electrical distribution network is illustrated, in accordance with examples of the technology disclosed herein. In such methods 300, the technology injects an active small-signal electrical stimulus at one or more stimulus source nodes—Block 310. In a continuing example citing features which can be independently present in a given embodiment, a session is configured by processor(s) 160 in which one or more of stimulus schedule, code patterns, measurement cadence, and target nodes are selected—enabling, e.g., concurrent multi-node sensing without net energy bias, e.g., by one or more DERs. In some such examples, time alignment is performed using distributed synchronization sufficient to align injections and measurements. In some such examples, the stimulus signals themselves assist synchronization. In some such examples, processors 160 issue control signals to inject active small-signal stimulus at one or more stimulus injectors 170 at source nodes according to the configured patterns.

In such methods 300, the technology detects stimulus-correlated responses at a plurality of measurement nodes of the network—Block 320. In the continuing example, during the scheduled stimulus windows, the technology collects stimulus-correlated voltage measurements from a plurality of LV measurement nodes and stimulus-correlated current measurements from one or more MV sensors positioned upstream of distribution transformers. In some examples, the technology collects MV node voltages. In some such examples, the technology (e.g., processor(s) 160) performs demodulation to correlate the acquired measurements against the known stimulus patterns (e.g., matched filtering or code correlation) to obtain stimulus-correlated measurement components. In some such examples, the technology organizes these components into per-node responses (e.g., delta-phasors or transfer gains) and then applies statistical or model-based corrections to mitigate the effects of one or more of interference, leakage currents, and root-voltage wander on the extracted responses.

In such methods 300, the technology estimates at least one model parameter indicative of the network structure or impedance based at least in part on the detected stimulus-correlated responses—Block 330. In the continuing example, the technology computes one or more model parameters indicative of network structure or impedance, including common impedances along shared conductor paths and upstream-downstream ancestry relationships between LV sources and MV assets. In some such examples, the technology executes state estimation over the modelled network to produce voltages, currents, and flows. In some such examples, the technology stores the estimated model and state and exposes them to external systems.

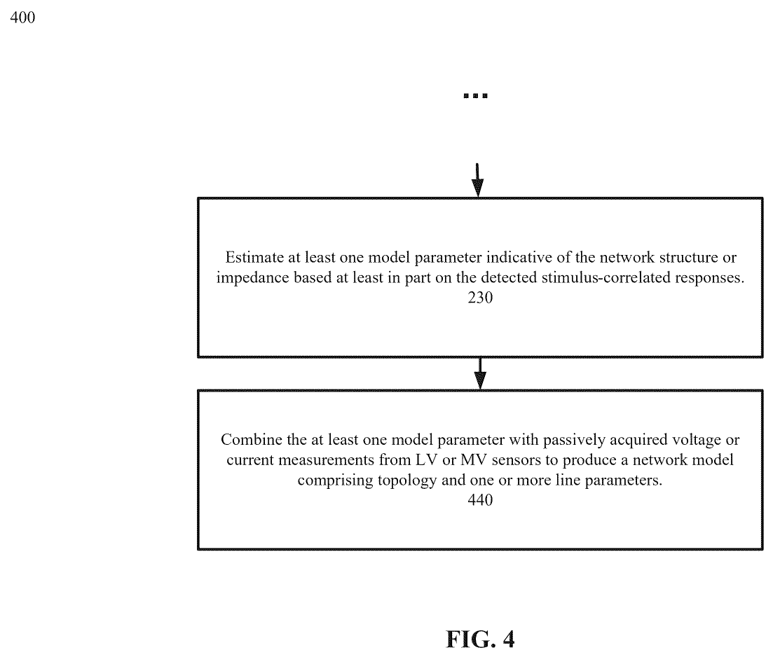

Referring to FIG. 4, and continuing to refer to prior figures for context, a flow chart of methods 400 of modeling an electrical distribution network is illustrated, in accordance with examples of the technology disclosed herein. In such methods 400, injection, detection, and estimating can be performed as described above in connection with Block 310, Block 320, and Block 330, respectively.

In such methods 400, the technology combines the at least one model parameter with passively acquired voltage or current measurements from LV or MV sensors to produce a network model comprising topology and one or more line parameters—Block 440. In the continuing example, in some such examples, the technology combines the stimulus-derived parameters with passively acquired measurements (whether time-synchronized or unsynchronized) from available sensors across processors distributed at the network edge, at accumulators, and among processor 160 to improve robustness and coverage. In some such examples, the technology constructs or corrects a network model comprising topology and one or more line parameters.

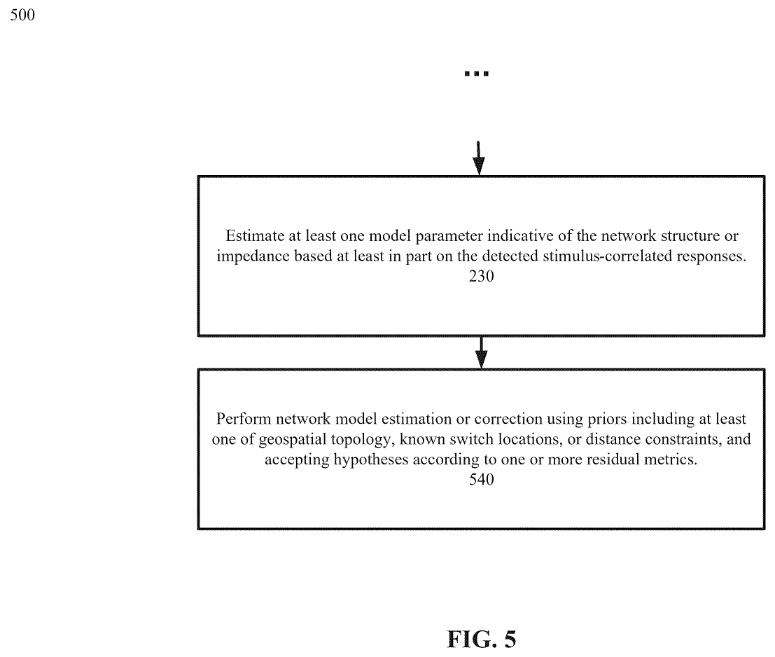

Referring to FIG. 5, and continuing to refer to prior figures for context, a flow chart of methods 500 of modeling an electrical distribution network is illustrated, in accordance with examples of the technology disclosed herein. In such methods 500, injection, detection, and estimating can be performed as described above in connection with Block 310, Block 320, and Block 330, respectively.

In such methods 500 the technology can perform network model estimation or correction using priors including at least one of geospatial topology, known switch locations, or distance constraints, and accepting hypotheses according to one or more residual metrics including at least one of total least squares or voltage-power covariance—Block 540. In some instances of the continuing example, after a scheduled session producing per-node responses and candidate common-impedance rows (Z) and ancestry indicators (K), the technology instantiates an initial hypothesis H₀ by snapping estimated leaves to nearby conductors in a geospatial base map and honoring known switch locations as hard constraints (e.g., prohibiting connectivity across an open switch, requiring continuity across a closed switch). Distance constraints derived from aerial/span lengths and parcel-to-secondary offsets bound feasible branch lengths and candidate transformer associations.

The technology, e.g., using processor(s) 160, then fits line and transformer parameters on H₀ under measurement-error-in-variables using total least squares to jointly accommodate noise in both dependent and independent variables. The resulting residuals (TLS branch residuals for impedance fits and voltage-power covariance misfit for passive P/Q/V data) are computed per branch and per device. If residual hot spots exceed thresholds or violate spatial smoothness implied by the distance constraints, the search module proposes local edits (e.g., swap a leaf to an adjacent secondary segment within the geospatial tolerance band, flip a phase assignment at a known multi-tap location, or move a transformer association within the allowable service-drop radius). Each edited hypothesis Hᵢ is re-fit (TLS) and re-scored on residual metrics, with acceptance only if residuals decrease and all priors remain satisfied. LV/MV ancestry edits are similarly bounded by MV sensor placement and known switch states; candidate reassignment of an LV subtree to a different MV phase is accepted only if MV current responses remain code-consistent and TLS residuals and voltage-power covariance both improve.

Once a hypothesis passes acceptance, the processor updates the model version, fuses any available passive telemetry (synchronized or unsynchronized) using a weighted TLS formulation where weights reflect SNR, synchronization quality, and geospatial confidence, and recomputes branch parameters under nonnegativity and symmetry constraints. The finalized hypothesis and parameters are persisted with residual summaries and confidence intervals, and the state estimator runs on the updated model to produce voltages and flows. In subsequent sessions, the same priors (geospatial topology, known switch locations, and distance bounds) and residual metrics (TLS, voltage-power covariance) drive incremental correction, ensuring that accepted edits are both physically plausible and statistically justified.

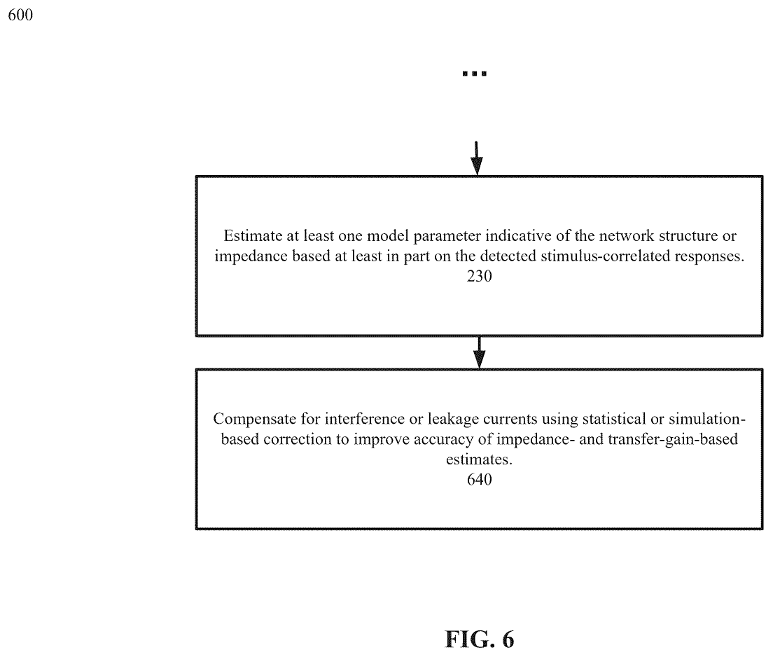

Referring to FIG. 6, and continuing to refer to prior figures for context, a flow chart of methods 600 of modeling an electrical distribution network is illustrated, in accordance with examples of the technology disclosed herein. In such methods 600, injection, detection, and estimating can be performed as described above in connection with Block 310, Block 320, and Block 330, respectively.

In such methods 600 the technology can compensate for interference or leakage currents using statistical or simulation-based correction to improve accuracy of impedance-and transfer-gain-based estimates—Block 640. The inputs for such compensation include: stimulus schedules and codes issued by the processor(s) 160 or injectors 170; stimulus-correlated LV voltage responses from LV sensors (e.g., sensors 180, meters, sub-meters, panel devices); stimulus-correlated MV current responses from MV sensors 190 positioned upstream of distribution transformers; demodulated components produced by narrowband filtering or code correlation (e.g., delta-phasors, per-node transfer gains); quality indicators such as symbol masks or outlier flags from the demodulation stage; and, where available, passive AMI/SCADA measurements and synchronization/timing metadata.
In some examples, modulation and demodulation are paired with orthogonal spreading codes to both separate simultaneously active sources and improve detectability through processing gain. Edges are aligned to voltage zero crossings, and each chip or symbol spans multiple cycles so that fast transients settle before measurement. Two concrete symbolizations are: (i) binary phase-shift keying implemented as bi-phase mark coding with two cycles per symbol, and (ii) BPSK placed on inter-harmonic tones (for example, ƒ=30+60n Hz, n=0, 1, 2, . . . ) so the probe remains well below the line frequency and avoids harmonics. Receivers recover stimulus-correlated components using narrowband extraction at the known modulation tone (e.g., FFT binning), and can compute delta-phasors or apply matched filtering against the expected step response. To constrain offset recovery, the receiver estimates local mains frequency and phase and aligns chip boundaries to zero crossings or stable cycle markers. Drift need not be “slow”; the processor treats cycle-to-cycle (delta-phasor) variation as the disturbance of interest and estimates/removes root-voltage wander referenced to the substation over sliding windows. Compensation for interference and leakage proceeds iteratively. The processor masks or down-weights symbols flagged by spectral or residual anomalies, models leakage/shunt effects (including via current-gain/K-matrix estimates) to de-bias V=IZ and transfer-gain estimates, and then re-solves the parameters. Residuals are computed as V=I·Z_filtered, where Z_filtered is constrained by the current topology hypothesis (rather than raw, unconstrained Z). The loop repeats: updating leakage/shunt priors and symbol masks—until residuals stabilize, maintaining code-division separability and operation without net energy bias. Simulation-based correction uses the current topology/parameter hypothesis to generate synthetic responses under the same stimulus, sweeping plausible leakage/shunt profiles; the profile that best aligns measured and simulated responses (by residual criteria) is selected, its corrections applied to the measurements, and the impedance and transfer-gain estimates re-solved to improve accuracy.

To validate and refine the corrections, the processor(s) 160 generate a feeder-specific simulation using the current topology hypothesis and nominal line/transformer parameters. It injects the same stimulus waveforms into the simulation while sweeping plausible leakage/shunt distributions drawn from priors, producing a library of synthetic responses. A Bayesian or Monte-Carlo calibration step selects the leakage/shunt profile that best aligns simulated and measured responses (e.g., by minimizing total-least-squares residuals across nodes), and the corresponding correction is applied to the measured data. Finally, the corrected responses are re-fit to yield common-impedance and transfer-gain estimates; branches whose residuals remain high are iteratively re-examined with tighter symbol masking or updated leakage priors. In field use, the system persists learned leakage parameters and drift statistics, using them as session-specific weights and priors so that subsequent estimates start from calibrated, low-bias conditions.

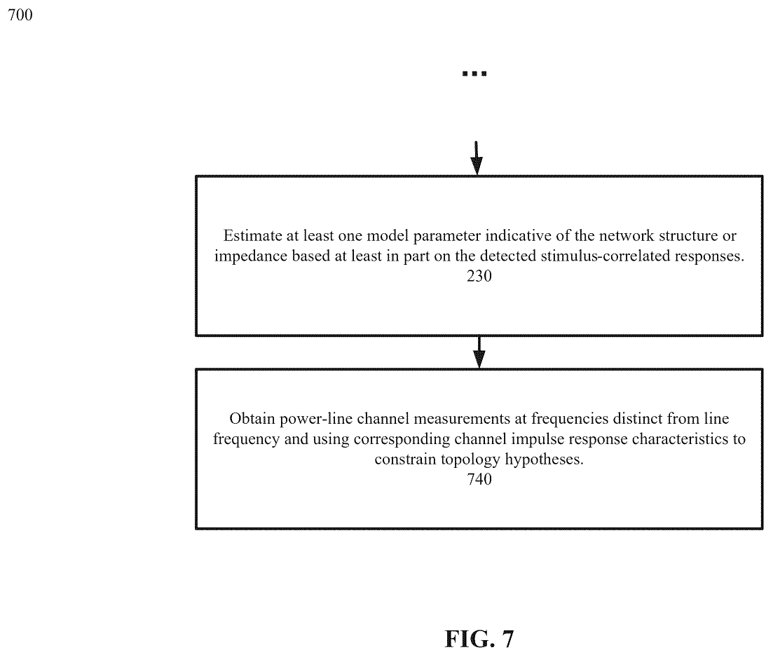

Referring to FIG. 7, and continuing to refer to prior figures for context, a flow chart of methods 700 of modeling an electrical distribution network is illustrated, in accordance with examples of the technology disclosed herein. In such methods 700, injection, detection, and estimating can be performed as described above in connection with Block 310, Block 320, and Block 330, respectively. In such methods 700 the technology obtains power-line channel measurements at frequencies distinct from line frequency and using corresponding channel impulse response characteristics to constrain topology hypotheses—Block 740.

In some instances of the continuing example, after measuring the resulting power-line channel responses between selected node pairs or between a node and the substation, the processor(s) estimate channel impulse response characteristics by correlating the received signals with the known probes or by spectral inversion of measured transfer functions. The resulting channel descriptors include features such as overall path loss and, where observable, multipath structure or delay spread indicative of branching.

In such instances, topology hypotheses are constrained using these channel characteristics. Candidate connections whose implied distances or branching patterns are inconsistent with the observed path-loss or delay features are down-weighted or eliminated; branch locations are bounded to segments whose channel signatures align with the measured responses. The remaining hypotheses are passed forward for parameter fitting and integration with the active, line-frequency stimulus-derived quantities, yielding a model that respects both the channel measurements and the stimulus-correlated impedance/ancestry information.

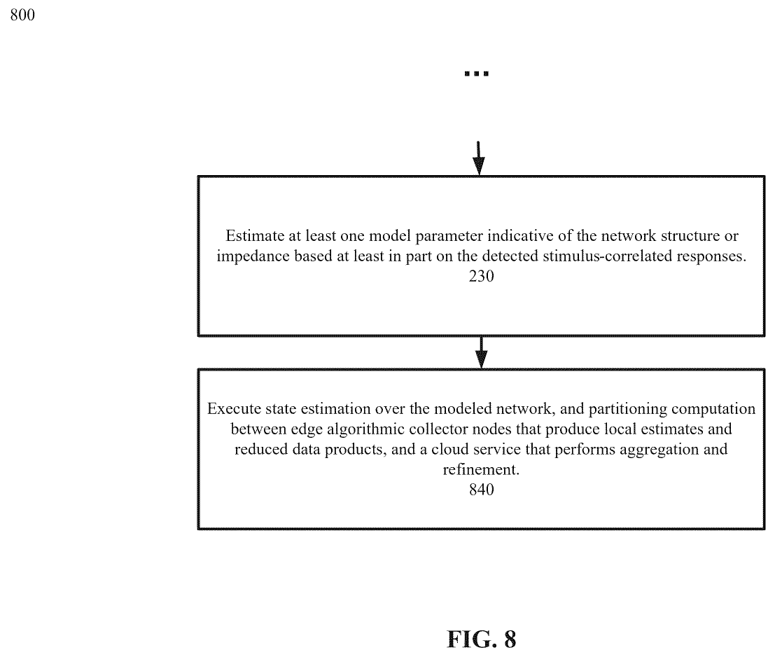

Referring to FIG. 8, and continuing to refer to prior figures for context, a flow chart of methods 700 of modeling an electrical distribution network is illustrated, in accordance with examples of the technology disclosed herein. In such methods 800, injection, detection, and estimating can be performed as described above in connection with Block 310, Block 320, and Block 330, respectively. In such methods 800 the technology executes state estimation over the modeled network, and partitioning computation between edge algorithmic collector nodes that produce local estimates and reduced data products, and a cloud service that performs aggregation and refinement—Block 840.

In some instances of the continuing examples, after detecting stimulus-correlated measurements produced locally (e.g. LV voltage responses from multiple endpoints and, where deployed, MV upstream current responses) together with any available passive measurements, each collector operates on its assigned subgraph (for example, an LV secondary or a local group of secondaries), forms reduced response products such as common-impedance row fragments and ancestry/current-gain indicators, and computes a preliminary network model for the subgraph. Using that subgraph model, the collector may execute local state estimation to produce voltages, currents, and flows, and summarizes results into reduced data products (e.g., Z/K fragments and local state estimates with associated residual/quality indicators) for transmission upstream, rather than sending raw waveforms.

A cloud (or central) processor 160 aggregates reduced data products from multiple collectors, aligns them by the known stimulus schedule and synchronization markers, and reconciles overlapping subgraphs to assemble a feeder-wide model spanning LV and MV. The processor refines topology and line/transformer parameters using the combined active-measurement products (and passive data when available), then executes feeder-level state estimation over the assembled model. Residual metrics are used to validate the feeder-level solution and to identify locations for follow-on measurement sessions or targeted refinement. This partitioning—local estimation and reduction at collectors, with aggregation and refinement centrally—reduces backhaul while enabling feeder-scale state estimation consistent with the disclosed architecture.

Some examples of the technology disclosed herein use active small-signal stimulus and stimulus-correlated detection across LV and MV portions of electrical power distribution networks. In such examples, the technology injects deliberate, low-amplitude electrical probe signals at selected network nodes (e.g., through distributed energy resources (DERs), controllable loads, or wall-plug devices) and detect stimulus-correlated responses at many measurement nodes. In some such examples, probe signals can be characterized by periodic or coded modulations (e.g., Gold codes, maximum-length sequences (MLS), bi-phase mark), including at non-60 Hz carriers. In some examples, code-division multiplexing permits simultaneous multi-node injections, minimizing the cross-correlation between codes, so the simultaneous injections do not “interfere” with each other (though we also have the ability to suppress this via decorrelation). In some examples, estimation methods include demodulating narrowband or symbol-level responses (delta-phasors or full waveform), then solving for impedance or current-gain parameters that encode shared-path relationships, branch points, and ancestry.

Some examples of the technology disclosed herein perform common-impedance estimation using LV stimulus with LV voltage sensors only. In some such examples, the technology estimates common impedance between stimulus source nodes and measurement nodes using only LV voltage responses at many endpoints, without requiring current measurement at the LV injector. In some such examples, the technology recovers shared conductor paths and local tree structure at LV, and aggregates pairwise observations to resolve higher-level topology and parameters. In some such examples, the technology relies on the accuracy of the stimulus device to inject the commanded current and does not need to measure a total current including uncontrolled loads.

Some examples of the technology disclosed herein perform ancestry sensing using LV stimulus and MV current sensors upstream of transformers. In some such examples, a small number of MV current sensors are positioned on feeders and some trunk segments; LV stimulus devices are activated and detected MV current signatures are correlated with LV sources to infer upstream-downstream relationships and transformer parameters. In some such examples, the technology can establish “what is downstream of what,” partition meters by feeder/phase, and obtain high-level MV topology and turns ratio/tap information.

Some examples of the technology disclosed hereon perform fusion of active parameters with passive measurements (synchronized or unsynchronized). In some examples the passive sources include advanced metering infrastructure (AMI)/supervisory control and data acquisition (SCADA) systems, utility meters, sub-meters, and transformer monitors. In some such examples, fusion includes combining stimulus-derived parameters (e.g., common impedance, ancestry) with passively acquired voltage/current or power data to produce unified network models encompassing topology and line parameters. Some such examples provide the benefits of one or more of reduced data requirements and improved robustness versus passive-only approaches. Some such examples support operation even when passive data are sparse or unsynchronized. Some such examples mitigate low coverage of active measurements, improving the detail of the estimated model and ensuring all load is accounted for in state estimation.

Some examples of the technology herein use time synchronization, including synchronization aided by the stimulus. In some such examples, the synchronization involves distributed timing for aligning injections and measurements. Some such examples include one or more of RF-mesh timing in GPS-denied environments and leveraging the known stimulus codes for alignment. In some such examples, processing can employ one or more of phasor-based (60 Hz aligned) or full-waveform demodulation and oversampling relative to the stimulus to reduce estimation noise.

In some examples, the technology uses priors and residual metrics in topology/model estimation. In some such examples, priors include one or more of: geospatial constraints, known switch locations, distance priors, and as-built GIS models. In some such examples, residual metrics include one or more of: least squares and total least squares; voltage-power covariance residuals; constraints (e.g., symmetry of Y, nonnegative real impedances); hypothesis sampling and pruning (e.g., beam search). Some such examples can accelerate and stabilize topology search/correction and parameter fitting under field noise.

In some examples, the technology compensates for interference and leakage current. In some examples, interference is addressed through one or more of: symbol masking of “suspect” intervals; decorrelation of overlapping codes; compensation for observed local currents; and estimation/removal of “root voltage wander.” In some examples, leakage-current is modelled through one or more of: correct V=IZ estimates for shunt/leakage effects at buses and inside nodes using statistical models and Monte Carlo or deterministic compensations. In some examples, such compensation can improve the accuracy of impedance and transfer-gain estimates under realistic field conditions.

In some examples, the technology employs edge/cloud compute partitioning and reduced backhaul. In such examples, the technology architecture includes “algorithmic collector” nodes that perform local estimation (e.g., local topology/impedance/state estimation) and transmit reduced data products upstream. Such approached can mitigate backhaul bottlenecks and improve scalability for feeder-wide deployments.

In some examples, the technology employs recursive grouping on common-impedance (RG, RG-common, and RG+). In such examples, the technology can infer tree topology (including hidden nodes) using impedance-derived distances and operate directly on the common-impedance matrix Z rather than effective impedance Zeff to simplify noise modeling. In some such examples, the technology can use probabilistic relationship tests (parent/child/sibling/none) with priors and likelihoods; pooling of repeated measurements of the same physical quantity to improve MV resolution; consistency enforcement; and efficiency and eligibility heuristics. In some examples the technology provides mixed-phase support, e.g., extending RG+ to multi- and mixed-phase networks by treating Z as a phase-phase matrix and applying phase masks and pooling operations.

In some examples, the technology employs multi-level LV/MV estimation pipelines. In some such examples, a virtual transformer approach, the technology can estimate LV topology first, then construct “virtual transformer” phasors at primaries, and perform MV topology search. This path can be sensitive to VT errors for MV search. In some such examples, a full Z approach, the technology can estimate a single Z matrix from LV data and exploit statistical structure to recover MV topology directly (e.g., many small MV impedances far from the diagonal can be pooled/averaged to improve resolution). This approach can simplify the pipeline and improve robustness.

In some examples, the technology employs search-based MV topology correction guided by a graph neural network (GNN). In such examples, the technology alternates between solving line parameters under a topology hypothesis and editing suspicious edges predicted by a GNN trained on residual patterns. Some such examples use beam search and geospatial constraints to propose reconnections. Such approached can provide improved noise tolerance over baselines in simulations, though with an error floor at high SNR, and are beneficial as a correction tool when starting from near-correct MV models.

In some examples, the technology employs power-line channel measurements and PLCC for topology constraints. In some such examples, the technology obtains channel impulse responses at frequencies distinct from line frequency (e.g., via PLCC or higher-frequency measurements). In some such examples, the technology uses the channel characteristics as additional constraints on topology hypotheses and parameter estimation.

In some examples, the technology employs interference mitigation and demodulation techniques including one or more of delta-phasors (cycle-to-cycle differences), PLL tracking, code decorrelation under masking, frequency selection to avoid harmonics or complement noise spectra, OFDM-like waveform synthesis for continuous control. Such approaches can improve SNR and separability of multiple simultaneous probes under realistic feeder noise.

In some examples, the technology employs distributed state estimation and “Live Wire” “T.N.T.” concepts. In such examples, the approach includes real-time state estimation, network model identification, and downstream applications (voltage management, constraint relief, DER coordination, DR targeting). In such examples, edge devices produce local estimates and reduced products, while cloud services aggregate and refine.

In general, stimulus provides deterministic separable signals to estimate common impedances and current gains quickly and robustly, enabling both LV structure recovery and MV ancestry/partitioning. RG+/Z-based topology estimation methods integrate those impedance measurements (and, where available, passive data and channel measurements) to reconstruct trees with hidden nodes, across phases. Priors, residual metrics, and search methods provide complementary pathways to correct model errors, particularly at MV. A modular hardware and compute architecture ensures scalable deployment, practical bandwidth, and incremental adoption, while interference/leakage compensation underpins accuracy in field environments.

“Phase/Trigger” Modulation Strategies on LV Secondaries—In some examples, load modulation on low-voltage (LV) secondaries is orchestrated to explicitly control phase participation and switching triggers so as to improve separability, reduce inter-phase interference, and raise signal-to-noise ratio in multi-phase environments. When three-phase or mixed-phase secondaries are present, enabling stimulus on all phases concurrently can cause voltage disturbances to appear at multiple points within each cycle and contaminate cross-phase demodulation, e.g., a phase B receiver attempting to estimate an A-to-B impedance will be dominated by larger same-phase transitions. To address this, phases can “take turns,” in which stimulus sources on phase A are activated while phases B and C remain quiescent, followed by a measurement window with stimulus only on phase B, then on phase C. This sequencing yields clean same-phase and cross-phase responses and avoids inter-phase interference at symbol boundaries, at the expense of longer overall measurement time. When phases take turns, cross-phase entries in the code sequence correlation matrix are zeroed during processing for the inactive phases. In some cases, the stimulus periods can be staggered but overlap so the transitions within each grid cycle are all on the same phase. (This is referenced below, making BPMC symbols longer than 2 cycles.)

In some examples involving center-tapped (split-phase) secondaries, the polarity of zero-crossing triggers used to control load modulation is altered so that load-step edges on the two half-phases occur at the same absolute time rather than being offset by 180 degrees. When resistive steps are aligned to voltage zero crossings, selecting consistent zero-crossing polarity across the split phases synchronizes the stimulus edges in time and suppresses spurious interleaving of transitions within a cycle, facilitating extraction of delta-waveforms and delta-phasors and improving estimation of same-phase and cross-phase impedance entries.

In some examples, code assignments are coordinated at the phase or feeder level to aggregate probe power while preserving separability. For instance, groups of devices sharing a secondary, transformer, feeder, or substation are assigned identical code sequences so that their contributions combine coherently at receivers, raising effective signal levels while maintaining a known codebook for decorrelation. In a multi-phase context, identical code assignment can be applied within a given phase during that phase's assigned “turn,” while distinct phases use disjoint time windows.

In some examples, chips are made longer (e.g., two or more cycles per symbol via bi-phase mark coding) and switching edges are cycle-aligned so that fast grid dynamics settle before demodulation. Where transmitters are asynchronous, symbol timing and phase/trigger alignment can be recovered algorithmically from voltage observations prior to code correlation. Collectively, these explicit phase/trigger strategies—phase-by-phase turn-taking, coordinated zero-crossing polarity selection on split-phase secondaries, and phase-or feeder-scoped identical code assignment to combine power—improve separability of same-phase and cross-phase responses and enable robust multi-phase common-impedance and transfer-gain estimation under realistic feeder noise.

Some examples include methods, systems, and non-transitory computer readable media for active load modulation on low-voltage secondaries of an alternating-current distribution network, comprising: during a measurement session, activating stimulus sources on a first phase of a multi-phase secondary while stimulus sources on one or more other phases are inactive, and subsequently activating stimulus sources on each of the other phases while the remaining phases are inactive, so that phases take turns to avoid inter-phase interference; aligning modulation edges to voltage zero crossings on the secondary and, for a center-tapped split-phase secondary, selecting zero-crossing polarity so that load changes on the split phases are synchronized in time rather than offset by 180 degrees; and assigning identical code sequences to a group of devices on a common secondary, transformer, feeder, or substation so that their probe currents combine coherently at receivers while remaining separable from other devices based on code correlation; wherein the phase turn-taking, zero-crossing polarity selection, and identical code assignment are used to produce stimulus-correlated voltage responses from which same-phase and cross-phase transfer quantities are extracted with reduced inter-phase interference.

Asynchronous Transmitters With Algorithmic Time-Offset Recovery—In some examples, stimulus transmitters operate without a shared time base, and receivers algorithmically recover per-transmitter time offsets from measured voltages before demodulation and parameter estimation. Receivers capture continuous voltage waveforms and identify the effective symbol timing and phase of each transmitter by correlating the observed delta-voltage against the transmitter's assigned code sequence. The correlation is evaluated over a sliding window or over hypothesized offsets, and the offset that maximizes correlation is selected as the transmitter's time alignment. Where codes include chip-level structure or duty-cycled steps, the receiver performs matched filtering to the expected step responses so that switching edges are localized in time despite asynchronous operation. After offset recovery, the receiver de-skews the voltage records to a common reference so that code correlation and transfer-gain estimation proceed as if the sources were synchronized.

In some examples, the receiver jointly estimates time offset and amplitude parameters by maximizing agreement between predicted voltage responses to the known stimulus sequence and the measured delta-voltage. The prediction accounts for settling windows following switching edges so that only steady-state portions of each chip contribute to the correlation score. The receiver can iterate between coarse alignment, using lower-rate correlation to bracket the offset, and fine alignment, using oversampled segments to refine the offset to sub-sample precision. When multiple transmitters are active, the receiver separates contributions by correlating to each transmitter's code, estimating a distinct offset for each, and subtracting reconstructed contributions to reduce multi-source interference prior to final demodulation.
In some examples, modulation and demodulation are paired with orthogonal spreading codes to both separate simultaneously active sources and improve detectability through processing gain. Edges are aligned to voltage zero crossings, and each chip or symbol spans multiple cycles so that fast transients settle before measurement. Two concrete symbolizations are: (i) binary phase-shift keying implemented as bi-phase mark coding with two cycles per symbol, and (ii) BPSK placed on inter-harmonic tones (for example, f=30+60n Hz, n=0, 1, 2, . . . ) so the probe remains well below the line frequency and avoids harmonics.

Receivers recover stimulus-correlated components using narrowband extraction at the known modulation tone (e.g., FFT binning), and can compute delta-phasors or apply matched filtering against the expected step response. Lengthening the spreading-code sequence increases processing gain and reduces noise approximately with the square root of the code length. Code-division at a common underlying modulation frequency maintains per-source separability while operating without net energy bias.

Some examples include methods, systems, and non-transitory computer readable media for operating a plurality of stimulus transmitters in an electrical distribution network, comprising: transmitting stimulus sequences from at least one transmitter without requiring a shared time base with a receiver; measuring voltage waveforms at the receiver during the transmission; correlating the measured voltage waveforms with a code sequence assigned to the transmitter to recover a time offset of the transmitter relative to the receiver; de-skewing the measured voltage waveforms based on the recovered time offset; and estimating a transfer quantity of the network from the de-skewed, code-correlated voltage, wherein the correlation is performed over hypothesized offsets to identify an offset that maximizes agreement with expected chip-level step responses and excludes settle intervals following switching edges.

Concrete Stimulus Frequency Ranges for Low-Frequency Load Modulation—In some examples, deliberate low-frequency modulation of load or source power is used to create a spectrally distinguishable signature for impedance and transfer-gain estimation. The modulation frequency is selected within concrete ranges disclosed herein. In one example, a periodic modulation in the range of approximately 0.1 Hz to 5 Hz is introduced to enhance detectability and improve signal-to-noise ratio while remaining compatible with distribution-network operating constraints. In another example, the modulation frequency ƒ_{mod} satisfies 1/(15×60) Hz<ƒ_{mod}<50/60 Hz, i.e., higher than a 15-minute interval and lower than the line frequency, so that the signature is narrowband, separable from slow ambient drift, and below the 50/60 Hz carrier. In a demonstrated instance, ƒ_{mod} is 0.125 Hz, corresponding to an eight-second toggle between two output levels, from which impedance to a virtual grid reference is extracted via spectral analysis.

In some examples, symbol design and demodulation are combined with orthogonal spreading-code sequences to improve detectability and noise immunity, in addition to enabling separation of multiple simultaneously active sources. Modulation edges are aligned to voltage zero crossings, and chips or symbols are expanded to span multiple cycles. For example, binary phase-shift keying implemented as bi-phase mark coding (two cycles per symbol) or at tones ƒ=30+60n Hz (n=0, 1, 2, . . . ) to encode impedance—so that fast transients settle before measurement and the probe remains well below line frequency. Receivers obtain stimulus-correlated components using narrowband extraction, including Fourier transforms evaluated at the known modulation frequency, and may compute delta-phasors or perform matched filtering against the expected step response. Using longer spreading-code sequences increases processing gain and reduces noise approximately with the square root of the code length, while code-division at a common underlying modulation frequency maintains per-source separability without net energy bias. Concrete session parameters illustrate performance tradeoffs at the stated frequency ranges.

In some examples, concrete session parameters illustrate performance tradeoffs at the stated frequency ranges. For instance, with a ±500 W stimulus and a 16-second period, employing spreading-code sequences of approximately eight minutes and FFT-based narrowband processing yields impedance noise on the order of 100 microohms. Increasing the spreading-code length reduces noise approximately with the square root of the increase in code length, because the spreading codes provide the effective oversampling and averaging gain. These settings keep the modulation well below line frequency, avoid harmonics, and support robust extraction of same-phase and cross-phase transfer quantities under realistic feeder noise.

Some examples include methods, systems, and non-transitory computer readable media for low-frequency active load modulation in an alternating-current distribution network, comprising: commanding a controllable source or load to vary a power exchange according to a periodic modulation at a frequency fmod that satisfies 1/(15×60) Hz<fmod<50/60 Hz, including examples where fmod is in a range of about 0.1 Hz to 5 Hz; measuring voltages at one or more nodes during the modulation; extracting a component corresponding to the modulation by narrowband spectral analysis at fmod or by matched filtering against an expected step response; and computing at least one transfer quantity or impedance indicative of shared electrical path between a transmitting node and a reference of the network; wherein modulation edges are aligned to voltage zero crossings and symbol duration is selected to allow settle time between edges so that steady-state portions contribute to the extracted component.

Specific Demod/Estimation Forms Using Pairwise Transfer Quantities—In some examples, demodulation and estimation are expressed in terms of explicit pairwise transfer quantities that divide stimulus-correlated voltage responses by an associated source current to yield impedances referenced to a virtual ground and shared-path impedances between node pairs. In a simple periodic session with one active source at a time, a controller configures a baseline output B, amplitude A, period P, and duration D; the source alternates between B and B±A, with switching edges aligned to the 50/60 Hz waveform. After each change in output, the system waits for the export/load to settle for a portion of the period (e.g., P/4) and then acquires voltage and current at the source (Vₛ, Iₛ) and voltages at other nodes (V₁ . . . V_{N}). Demodulation may be performed by extracting a fundamental component at ƒ=1/P (e.g. via FFT) and then de-spreading the bi-phase-mark coding with a known orthogonal sequence, e.g. Gold Code. The source current Is provides the denominator for transfer quantities. From these data, the system calculates impedance at the source node to a common feeder ground as Vₐₐ/Iₐ and, for each measurement node ₓ, calculates the shared line impedance to a virtual ground as Vₓₐ/Iₐ. These quantities represent the impedance of the distribution line and/or private, sub-meter wiring shared by node X and the source to the virtual ground or upstream transmission reference.

In some examples, multiple sources are active concurrently under coded modulation, and receivers compute pairwise transfer quantities by sequentially applying code sequences to separate contributions. A session is configured with Sources 1 . . . N, baseline B, amplitude A, period P, duration D, and location codes (C₁ . . . C_{N}). After settle intervals (e.g., P/4) following each change in export/load, nodes measure source voltage and current (Vₛ, Iₛ) and remote voltages (V₁ . . . V_{N}). At each node a, the receiver sequentially applies codes C_{b}, cycling b from 1 to N, to decode the voltage change attributable to source a at node b, producing V_{ab}. The node-wise pairwise transfer quantities V_{ab}/Iₐ and Vₐₐ/Iₐ are then computed, with the latter giving the impedance at node a to a virtual ground and the former giving the shared line impedance between node a and node b referenced to the same current Iₐ. Where bi-phase mark coding is used, chips are expanded (e.g., two cycles per symbol) so that at least one cycle of steady-state response is measured; demodulation proceeds by differencing consecutive cycles within a symbol and multiplying by ±1 according to the code.

In some examples, a linear algebraic formulation using code correlation is used to improve the accuracy of pairwise transfer quantities when many sources operate simultaneously or when masking alters code orthogonality. Voltages are organized as delta-phasor arrays VΔ, obtained from cycle-aligned phasors or full-waveform differencing. The injected current delta-phasors are modeled as IΔ=Dₛₜᵢₘ S, where Dₛₜᵢₘ is diagonal with per-source current scales and S is a matrix of ±1 code symbols (after any time-domain masking). The received voltages satisfy VΔ=Z Dₛₜᵢₘ S, with Z the common-impedance matrix whose entries encode pairwise transfer gains. Demodulation multiplies by S^{T} to yield V_{demod}=Z Dₛₜᵢₘ C, where C=S S^{T} is the code cross-correlation matrix. Solving the resulting linear system in transposed form, C Dₛₜᵢₘ Z^{T}=V^{T}_{demod}, yields Z and thereby the pairwise quantities Zᵢⱼ that correspond to Vᵢⱼ/Iⱼ under the stated scaling. In these examples, code decorrelation recovers clean pairwise transfer quantities even when codes are not perfectly orthogonal, when symbol masking is applied, or when injected current magnitudes differ across sources.

Some examples includes methods, systems, and non-transitory computer readable media for estimating electrical impedances on a distribution network using pairwise transfer quantities, comprising: commanding at least one source to vary power according to a periodic or coded modulation; after each change in output, waiting for a settle interval that is a fraction of a modulation period and acquiring a source current Is and voltages at the source and at one or more remote nodes; demodulating the measured voltages to obtain per-source, per-node voltage responses, including by sequentially applying location codes to decode, at a node a, a voltage change attributable to a source at node b to produce V_{ab}; and computing pairwise transfer quantities by dividing the decoded voltages by the associated source current, including Vₐₐ/Iₐ as an impedance at node a to a local neutral and V_{ab}/Iₐ as a shared line impedance between node a and node b; wherein oversampling relative to the modulation period and decorrelation using a code cross-correlation matrix are applied to reduce interference and improve accuracy of the pairwise transfer quantities.

Passive-Only Ancestry/Phase-Inference Methods (No Stimulus)—In some examples, ancestry and phase relationships are inferred using passively acquired measurements without any deliberate stimulus. In one approach, passive current sensing is used to detect upstream-downstream relationships by regressing trunk currents against downstream meter currents over time. In this formulation, an N×T matrix H of passively measured meter currents (N meters, T time samples) and an M×T matrix A of passively measured trunk currents (M trunk sensors, T time samples) are collected. A least-squares regression estimates an M×N matrix of current-gain coefficients K such that A≈K H; entries of K indicate whether and how a given meter contributes to current observed at a trunk sensor. The signed ancestry is identified by rounding or thresholding the estimated coefficients to {−1, 0, +1}, where nonzero entries denote that the trunk measurement point is an ancestor of the corresponding meter, with sign reflecting circuit polarity. This passive-only ancestry method can function with one or more phases per trunk and accommodates the case where meters must be classified as “not an ancestor” with respect to particular trunk sensors. Performance improves with higher temporal resolution and when meter power profiles exhibit sufficient diversity so that H has well-conditioned columns; low-rate, highly correlated profiles reduce separability.

In another approach, ancestry and phase association are inferred by correlating passive voltage time series across transformers or secondaries to detect common feeder and phase. When voltage measurements are available on the LV side of a transformer, the method first approximately compensates secondary voltage drops by fitting coefficients that relate local real and reactive power to measured voltage magnitude, and then applies the correction to form an adjusted voltage signal. For each sensor pair, a correlation coefficient is computed between their adjusted voltage time series; if the correlation exceeds a threshold (for example, greater than 0.8 over a sufficiently long window), the transformers are inferred to be on the same feeder and phase. Empirical correlation matrices over multi-day intervals exhibit block structures in which same-feeder, same-phase groupings present high correlations, cross-feeder correlations are lower, and cross-substation correlations are near zero. This passive-only voltage correlation method operates with unsynchronized or loosely synchronized data provided the sampling cadence and window length are sufficient to suppress slow drift and reveal coherent variations within a feeder-phase.

In some examples, these passive methods are incorporated into a broader pipeline as sources of constraints or priors for topology estimation and phase labeling. Passive ancestry via current regression yields a binary or signed mask identifying, for each trunk sensor, the set of meters downstream, and can be used to partition meters by feeder segment before impedance-based topology estimation. Passive voltage correlation yields clusters of transformers sharing a phase, which can be used to initialize or validate phase assignments prior to or in lieu of any active measurement. Both methods are compatible with mixed sensing coverage: where trunk current sensors are sparse, voltage-correlation groupings can still identify same-feeder/phase sets; where meter coverage is high and profiles are diverse, current-regression ancestry can be computed at finer granularity. These passive-only inferences improve robustness when active probing is unavailable and can be fused with other passive data sources to produce unified network models.

Some examples include methods, systems, and non-transitory computer readable media for inferring distribution-network ancestry and phase association without injecting a deliberate stimulus, comprising: acquiring, over time, passive electrical measurements selected from trunk currents at one or more upstream locations and voltages or currents at a plurality of downstream meters; estimating an ancestry relationship between the upstream locations and the meters by regressing the trunk-current measurements against the meter-current measurements to obtain a current-gain matrix whose entries, when thresholded or rounded, indicate whether a trunk location is an ancestor of a given meter; computing, from passively acquired voltage measurements at transformers or secondaries, pairwise correlation coefficients between adjusted voltage time series formed by compensating for secondary-side voltage drop as a function of local real and reactive power; and assigning same-feeder and same-phase associations to sensors whose adjusted-voltage correlation exceeds a threshold, wherein the ancestry and phase associations are determined solely from passive measurements without any active load modulation.

Compliance/Interface Details for MV Sensors (IEEE C37.118 PMU interface)—In some examples, medium-voltage (MV) sensors provide synchrophasor outputs conforming to an IEEE C37.118-style interface for PMU data to enable interoperability with existing vendor equipment and simplify integration into utility workflows. MV synchrophasors compliant with the PMU data interface can be consumed alongside data streams from third-party PMUs (e.g., SEL or GE devices) and ingested by a software platform that partitions computation between the edge and the cloud, thereby broadening acceptance where utilities are already deploying distribution-level synchrophasors. In these examples, the MV sensors report synchronized measurements of voltage and current phasors and may include rate-of-change metrics such as ROCOF and ROCOV, consistent with distribution-grid state estimation needs. A three-phase synchrophasor payload is on the order of kilobits per report, and the required reporting frequency determines the backhaul bandwidth; therefore, the MV interface supports configurable reporting rates and edge processing that reduce data volume by transmitting locally computed results or reduced data products when appropriate.

In some examples, the MV PMU interface operates within a system architecture that recognizes constraints in timing and communications on distribution feeders. Because MV and LV assets may lack reliable access to satellite time, only a subset of devices may carry absolute time references while others achieve precise inter-sensor synchronization without GPS. In such deployments, the PMU interface supports synchronized operation across heterogeneous timing sources and enables the software platform to fuse PMU data with other synchronized or unsynchronized measurements. Where communications backhaul is limited, edge “algorithmic collector” nodes co-located with MV sensors pre-process synchrophasors and forward compressed estimates, improving scalability while preserving compatibility with PMU data consumers.

In some examples, MV sensors exposing a PMU-standard interface are part of a modular sensing platform spanning LV and MV domains. This platform uses MV synchrophasors, optionally together with LV measurements and active or passive parameters, to support topology identification and distributed state estimation. The ability to interoperate at the MV layer via an IEEE C37.118-style interface allows the platform to mix and match MV devices from multiple vendors, accelerate prototyping, and integrate PMU streams already present on feeders, while maintaining a single processing pipeline for network model identification and state estimation.

Some examples include systems, methods, and non-transitory computer readable media for distribution-network sensing comprising a medium-voltage sensor configured to output synchronized phasor measurements via an interface compliant with a synchrophasor standard for power systems, the interface being compatible with phasor measurement unit data used by third-party devices, and a processor configured to: ingest the synchronized phasor measurements together with other synchronized or unsynchronized measurements from the distribution network; optionally perform edge pre-processing at or near the sensor to reduce communications backhaul while preserving information content; and produce state estimates or network model parameters using the ingested data; wherein the synchronized phasor measurements include voltage and current phasors and one or more rate-of-change quantities suitable for distribution-level state estimation, and the compliant interface enables interoperability with existing vendor PMUs deployed on the medium-voltage network.

Recursive Grouping Plus—In some examples, a topology and parameter estimation engine employs recursive grouping plus (RG+) operating directly on a common-impedance matrix Z rather than an effective-impedance matrix Z_{eff}. By working on Z, which encodes common path impedances to a root and admits a simpler noise model, RG+ can recover parent-child relationships, sibling groups, and hidden nodes with improved robustness. RG+ formulates node-relationship tests in a probabilistic framework: for each node pair, likelihoods and posteriors are computed over relationship states (unrelated, parent/child, child/parent, siblings) under priors and a measurement-likelihood model for the observed Z entries and summary statistics thereof. The engine pools repeated measurements of the same physical quantity (e.g., Z entries that observe the same upstream self-impedance) to reduce variance and improve resolution, including for medium-voltage structure inferred from small Z entries far from the diagonal. Relationship selections are enforced for consistency using constraints such as sibling transitivity, common parentage of sibling cliques, and acyclicity of parent-child links. Efficiency and eligibility heuristics reduce computation by prioritizing informative pairs and deferring comparisons with small Z[m, n] magnitudes. In some examples, RG+is extended to multi-and mixed-phase networks by treating Z as a phase-phase matrix, applying phase masks, and pooling phase-wise quantities so that relationship testing proceeds with phase-aware statistics while preserving the bottom-up grouping workflow.

In some examples, RG+ can be combined with hypothesis sampling or beam-search style pruning, priors (e.g., geospatial constraints, known switches, and distance bounds), and residual metrics (e.g., total least squares and voltage-power covariance) to initialize, constrain, or refine the topology produced from Z. The resulting pipeline iteratively estimates Z from active and/or passive measurements, applies RG+ to assemble a tree with hidden nodes across phases, and uses pooled Z structure to propagate uncertainty reduction up the hierarchy. These approaches allow LV topology to be reconstructed from LV measurements and, where sufficient pooling is available, MV ancestry and structure to be resolved from the same Z matrix.

Some examples include computer-implemented methods, systems, and non-transitory computer readable media for estimating an electrical distribution-network topology, including: forming, by one or more processors, a common-impedance matrix Z from electrical measurements at a plurality of nodes; for each pair of nodes in an active set, computing, under a probabilistic model, likelihoods of relationship states selected from unrelated, parent-child, and siblings based on entries of Z; enforcing global relationship-consistency constraints including at least acyclicity of parent-child links, common parentage of sibling cliques, and transitivity of sibling grouping; selecting relationships according to posterior probabilities to form sibling cliques and parent-child connections, inferring hidden parent nodes for sibling cliques, and updating the active set by removing nodes whose parents have been determined and adding inferred hidden parents; pooling repeated observations of a same underlying common impedance across entries of Z to reduce variance; and iteratively repeating the computing, enforcing, selecting, inferring, updating, and pooling until a tree topology with hidden nodes and branch impedances is produced, wherein the computing, enforcing, selecting, inferring, updating, and pooling operate directly on the common-impedance matrix Z rather than on an effective-impedance matrix, and optionally employing beam search or hypothesis pruning to manage candidate relationship sets.

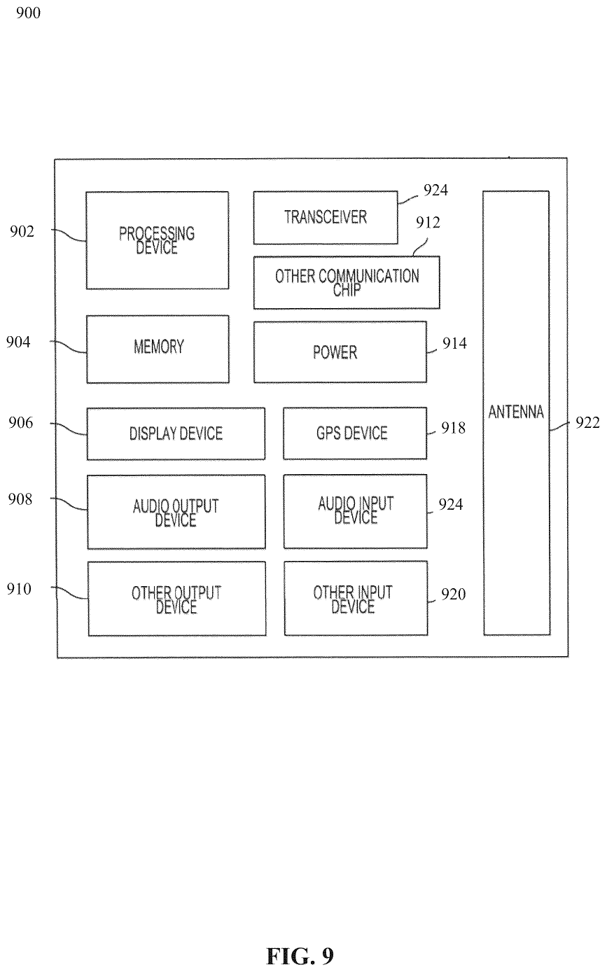

Examples of the present disclosure may be implemented into a system using any suitable hardware and/or software to configure as desired. Referring to FIG. 9, and continuing to refer to prior figures for context, FIG. 9 schematically illustrates a device 900 that may serve as a computer/processor, in accordance with various examples. A number of components are illustrated in FIG. 9 as included in the device 900, but any one or more of these components may be omitted or duplicated, as suitable for the application. In some examples, device 900 can include be a metering device, and can include a signal chain (V/I measurement interfacing to resistive divider, PT/CT, Rogowski coil etc.).

Additionally, in various examples, the device 900 may not include one or more of the components illustrated in FIG. 9, but the device 900 may include interface circuitry for coupling to the one or more components. For example, the device 900 may not include a display device 906, but may include display device interface circuitry (e.g., a connector and driver circuitry) to which a display device 906 may be coupled. In another set of examples, the device 900 may not include an audio input device 924 or an audio output device 908 but may include audio input or output device interface circuitry (e.g., connectors and supporting circuitry) to which an audio input device 924 or audio output device 908 may be coupled.

The device 900 may include a transceiver 924, in accordance with any of the examples disclosed herein, for managing communication along the bus when the device 900 is coupled to the bus. The device 900 may include a processing device 902 (e.g., one or more processing devices), which may be included in the node transceiver or separate from the node transceiver. As used herein, the term “processing device” may refer to any device or portion of a device that processes electronic data from registers and/or memory to transform that electronic data into other electronic data that may be stored in registers and/or memory. The processing device 902 may include one or more DSPs, ASICs, central processing units (CPUs), graphics processing units (GPUs), crypto-processors, or any other suitable processing devices. The device 900 may include a memory 904, which may itself include one or more memory devices such as volatile memory (e.g., dynamic random-access memory (DRAM)), non-volatile memory (e.g., read-only memory (ROM)), flash memory, solid state memory, and/or a hard drive.

In some examples, the memory 904 may be employed to store a working copy and a permanent copy of programming instructions to cause the device 900 to perform any suitable ones of the techniques disclosed herein. In some examples, machine-accessible media (including non-transitory computer-readable storage media), methods, systems, and devices for performing the above-described techniques are illustrative examples disclosed herein for communication over a two-wire bus. For example, a computer-readable media (e.g., the memory 904) may have stored thereon instructions that, when executed by one or more of the processing devices included in the processing device 902, cause the device 900 to perform any of the techniques disclosed herein.

In some examples, the device 900 may include another communication chip 912 (e.g., one or more other communication chips). For example, the communication chip 912 may be configured for managing wireless communications for the transfer of data to and from the device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some examples they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The one or more communication chips 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The one or more communication chips 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The one or more communication chips 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other examples. The device 900 may include an antenna 922 to facilitate wireless communications and/or to receive other wireless communications (such as AM or FM radio transmissions). In some examples, the device implements a software radio—allowing a single chip line that can be field programmable to interface with different radio standards.

In some examples, the communication chip 912 may manage wired communications using a protocol other than the protocol for the bus described herein. Wired communications may include electrical, optical, or any other suitable communication protocols. Examples of wired communication protocols that may be enabled by the communication chip 912 include Ethernet, controller area network (CAN), I2C, media-oriented systems transport (MOST), or any other suitable wired communication protocol.

As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as global positioning system (GPS), EDGE, GPRS, CDMA, WiMAX, LTE, EV-DO, or others. In some examples, a first communication chip 912 may be dedicated to wireless communications, and a second communication chip 912 may be dedicated to wired communications.

The device 900 may include battery/power circuitry 914. The battery/power circuitry 914 may include one or more energy storage devices (e.g., batteries or capacitors) and/or circuitry for coupling components of the device 900 to an energy source separate from the device 900 (e.g., AC line power, voltage provided by a car battery, etc.).

The device 900 may include a display device 906 (or corresponding interface circuitry, as discussed above). The display device 906 may include any visual indicators, such as a heads-up display, a computer monitor, a projector, a touchscreen display, a liquid crystal display (LCD), a light-emitting diode display, or a flat panel display, for example.

The device 900 may include an audio output device 908 (or corresponding interface circuitry, as discussed above). The audio output device 908 may include any device that generates an audible indicator, such as speakers, headsets, or earbuds, for example.

The device 900 may include an audio input device 924 (or corresponding interface circuitry, as discussed above). The audio input device 924 may include any device that generates a signal representative of a sound, such as microphones, microphone arrays, or digital instruments (e.g., instruments having a musical instrument digital interface (MIDI) output).

The device 900 may include a GPS device 918 (or corresponding interface circuitry, as discussed above). The GPS device 918 may be in communication with a satellite-based system and may receive a location of the device 900, as known in the art.

The device 900 may include another output device 910 (or corresponding interface circuitry, as discussed above). Examples of the other output device 910 may include an audio codec, a video codec, a printer, a wired or wireless transmitter for providing information to other devices, or an additional storage device. Additionally, any suitable ones of the peripheral devices may be included in the other output device 910.

The device 900 may include another input device 920 (or corresponding interface circuitry, as discussed above). Examples of the other input device 920 may include an accelerometer, a gyroscope, an image capture device, a keyboard, a cursor control device such as a mouse, a stylus, a touchpad, a bar code reader, a Quick Response (QR) code reader, or a radio frequency identification (RFID) reader. Additionally, any suitable ones of the sensors or peripheral devices may be included in the other input device 920.

Any suitable ones of the display, input, output, communication, or memory devices described above with reference to the device 900 may serve as the peripheral device in system of the technology disclosed herein. Alternatively or additionally, suitable ones of the display, input, output, communication, or memory devices described above with reference to the device 900 may be included in a host or a node (e.g., a main node or a sub node).

Although various ones of the examples discussed above describe the system of the technology disclosed herein in a vehicle setting, this is simply illustrative, and the system of the technology disclosed herein may be implemented in any desired setting.

Having thus described several aspects and examples of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the examples described herein.

Those skilled in the art will recognize or be able to ascertain using no more than routine experimentation, many equivalents to the specific examples described herein. It is, therefore, to be understood that the foregoing examples are presented by way of example only and that, within the scope of the appended claims and equivalents thereto, inventive examples may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more examples of the subject matter disclosed herein. These examples are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the examples introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described examples may be implemented in any of numerous ways. One or more aspects and examples of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various examples described above.

The computer readable medium or media may be transportable, such that the program or programs stored thereon may be loaded onto one or more different computers or other processors to implement various ones of the aspects described above. In some examples, computer readable media may be non-transitory media.

Note that the activities discussed above with reference to the figures which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or DSP) to perform the methods or functions disclosed herein. In cases where the teachings herein are embodied at least partly in a hardware device (such as an ASIC, IP block, or SoC), a non-transitory medium could include a hardware device hardware-programmed with logic to perform the methods or functions disclosed herein. The teachings could also be practiced in the form of Register Transfer Level (RTL) or other hardware description language such as VHDL or Verilog, which can be used to program a fabrication process to produce the hardware elements disclosed.

In example implementations, at least some portions of the processing activities outlined herein may also be implemented in software. In some examples, one or more of these features may be implemented in hardware provided external to the elements of the disclosed figures or consolidated in any appropriate manner to achieve the intended functionality. The various components may include software (or reciprocating software) that can coordinate in order to achieve the operations as outlined herein. In still other examples, these elements may include any suitable algorithms, hardware, software, components, modules, interfaces, or objects that facilitate the operations thereof.

Any suitably configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, an FPGA, an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, element, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various examples, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Computer-executable instructions may be in many forms, such as program modules, executed by one or more computers or other devices. Generally, program modules include routines, programs, objects, components, data structures, etc. that performs particular tasks or implement particular abstract data types. Typically, the functionality of the program modules may be combined or distributed as desired in various examples.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, a computer-implemented method wit memory storing code/instructions therein, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some examples, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, examples may be constructed in which acts are performed in an order different than illustrated, which may include performing some acts simultaneously, even though shown as sequential acts in illustrative examples.

### Interpretation of Terms

All definitions, as defined and used herein, should be understood to control over dictionary definitions, definitions in documents incorporated by reference, and/or ordinary meanings of the defined terms. Unless the context clearly requires otherwise, throughout the description and the claims: “comprise,” “comprising,” and the like are to be construed in an inclusive sense, as opposed to an exclusive or exhaustive sense; that is to say, in the sense of “including, but not limited to.” “Connected,” “coupled,” or any variant thereof, means any connection or coupling, either direct or indirect, between two or more elements. The coupling or connection between the elements can be physical, logical, or a combination thereof. “Herein,” “above,” “below,” and words of similar import, when used to describe this specification shall refer to this specification as a whole and not to any particular portions of this specification. “Or,” in reference to a list of two or more items, covers all of the following interpretations of the word: any of the items in the list, all of the items in the list, and any combination of the items in the list. The singular forms “a,” “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one example, to A only (optionally including elements other than B); in another example, to B only (optionally including elements other than A); in yet another example, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one example, to at least one, optionally including more than one, A, with no B present (and optionally including elements other than B); in another example, to at least one, optionally including more than one, B, with no A present (and optionally including elements other than A); in yet another example, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular examples described above. Various modifications, equivalent processes, as well as numerous structures to which the present invention may be applicable, will be readily apparent to those skilled in the art to which the present invention is directed upon review of the present disclosure.

It should be understood that the detailed description and specific examples, while indicating examples of the systems and methods are intended for purposes of illustration only and are not intended to limit the scope. These and other features, aspects, and advantages of the systems and methods of the present invention can be better understood from the description, appended claims, or aspects, and accompanying drawings. It should be understood that the Figures are merely illustrative and are not drawn to scale. It should also be understood that the same reference numerals are used throughout the figures to indicate the same or similar parts.

Other variations to the disclosed examples can be understood and effected by those skilled in the art in practicing the disclosure, from a study of the drawings, the disclosure, and the appended aspects or claims. In the aspects or claims, the word “comprising” does not exclude other elements or steps, and the indefinite article “a” or “an” does not exclude a plurality. The mere fact that certain measures are recited in mutually different dependent aspects or claims does not indicate that a combination of these measures cannot be used to advantage. Any reference signs in the claims should not be construed as limited the scope.

What is claimed is:

1. A method for modeling an electrical distribution network spanning low-voltage (LV) and medium-voltage (MV) portions, comprising:
injecting, at one or more stimulus source nodes, an active small-signal electrical stimulus;
detecting stimulus-correlated responses at a plurality of measurement nodes of the network and
estimating at least one model parameter indicative of the network structure or impedance based at least in part on the detected stimulus-correlated responses.

2. The method of claim 1, wherein the at least one model parameter comprises an ancestry relationship between one or more stimulus source nodes and one or more measurement nodes.

3. The method of claim 1, wherein the at least one model parameter comprises a common impedance between one or more stimulus source nodes and one or more measurement nodes along one or more shared conductor paths.

4. The method of claim 1, wherein detecting stimulus-correlated responses comprises detecting, with voltage sensors at a plurality of nodes, stimulus-correlated voltage responses; and wherein estimating the at least one model parameter includes estimating common impedance without requiring a current measurement at the one or more stimulus source nodes.

5. The method of claim 1, wherein detecting stimulus-correlated responses comprises detecting, with one or more MV current sensors positioned upstream of a distribution transformer, stimulus-correlated current responses, and the estimating includes determining at least one of upstream-downstream ancestry relationships and transformer parameters between LV and MV assets.

6. The method of claim 1, further comprising combining the at least one model parameter with passively acquired voltage or current measurements from LV or MV sensors to produce a network model comprising topology and one or more line parameters.

7. The method of claim 6, wherein the passively acquired measurements are time-synchronized or unsynchronized.

8. The method of claim 1, wherein injecting and detecting are time-synchronized across nodes using distributed time synchronization, and optionally using the stimulus to facilitate synchronization.

9. The method of claim 1, further comprising performing network model estimation or correction using priors including at least one of geospatial topology, known switch locations, or distance constraints, and accepting hypotheses according to one or more residual metrics.

10. The method of claim 1, further comprising compensating for interference or leakage currents using statistical or simulation-based correction to improve accuracy of impedance-and transfer-gain-based estimates.

11. The method of claim 1, further comprising obtaining power-line channel measurements at frequencies distinct from line frequency and using corresponding channel impulse response characteristics to constrain topology hypotheses.

12. The method of claim 1, wherein the active small-signal electrical stimulus is patterned to permit concurrent multi-node sensing without net energy bias and is generated by one or more distributed energy resources.

13. The method of claim 1, further comprising executing state estimation over the modeled network, and partitioning computation between edge algorithmic collector nodes that produce local estimates and reduced data products, and a cloud service that performs aggregation and refinement.

14. A system comprising: one or more LV voltage sensors, one or more MV current sensors, and one or more stimulus injectors; and one or more processors configured to: issue control signals to inject an active small-signal electrical stimulus at one or more stimulus source nodes; receive stimulus-correlated responses detected at a plurality of measurement nodes; and estimate at least one model parameter indicative of the network structure or impedance based at least in part on the detected stimulus-correlated responses.

15. The system of claim 14, wherein the one or more processors are configured to estimate an ancestry relationship between one or more stimulus source nodes and one or more measurement nodes based at least in part on stimulus-correlated current responses detected by the one or more MV current sensors positioned upstream of a distribution transformer.

16. The system of claim 14, wherein the one or more processors are configured to estimate common impedance between one or more stimulus source nodes and one or more measurement nodes along shared conductor paths, without requiring a current measurement at the one or more stimulus source nodes.

17. The system of claim 14, wherein the one or more processors are configured to combine the at least one estimated model parameter with passively acquired voltage or current measurements from LV or MV sensors, whether time-synchronized or unsynchronized, to produce a network model comprising topology and one or more line parameters.

18. The system of claim 14, wherein the one or more processors are configured to synchronize injections and measurements across nodes using distributed time synchronization, optionally leveraging the stimulus signals themselves.

19. The system of claim 14, wherein the one or more processors are configured to:
form, by the one or more processors, a common-impedance matrix Z from electrical measurements at a plurality of nodes;
for each pair of nodes in an active set, compute, under a probabilistic model, likelihoods of relationship states selected from unrelated, parent-child, and siblings based on entries of Z;
enforce global relationship-consistency constraints including at least acyclicity of parent-child links, common parentage of sibling cliques, and transitivity of sibling grouping;
select relationships according to posterior probabilities to form sibling cliques and parent-child connections, inferring hidden parent nodes for sibling cliques, and updating the active set by removing nodes whose parents have been determined and adding inferred hidden parents;
pool repeated observations of a same underlying common impedance across entries of Z to reduce variance; and
iteratively repeat the computing, enforcing, selecting, inferring, updating, and pooling until a tree topology with hidden nodes and branch impedances is produced,
wherein the computing, enforcing, selecting, inferring, updating, and pooling operate directly on the common-impedance matrix Z rather than on an effective-impedance matrix, and optionally employing beam search or hypothesis pruning to manage candidate relationship sets.

20. A non-transitory computer-readable medium storing instructions that, when executed by one or more processors, cause the one or more processors to perform operations comprising: issuing control signals to inject an active small-signal electrical stimulus at one or more LV stimulus source nodes; receiving stimulus-correlated responses detected at a plurality of measurement nodes; and estimating at least one model parameter indicative of the network structure or impedance based at least in part on the detected stimulus-correlated responses.

21. The non-transitory computer-readable medium of claim 20, wherein the operations further comprise estimating an ancestry relationship between one or more stimulus source nodes and one or more measurement nodes based at least in part on stimulus-correlated current responses detected by one or more MV current sensors positioned upstream of a distribution transformer.

22. The non-transitory computer-readable medium of claim 20, wherein the operations further comprise estimating common impedance between one or more stimulus source nodes and one or more measurement nodes along shared conductor paths without requiring a current measurement at the one or more stimulus source nodes.

23. The non-transitory computer-readable medium of claim 20, wherein the operations further comprise combining the at least one estimated model parameter with passively acquired voltage or current measurements from LV or MV sensors, whether time-synchronized or unsynchronized, to produce a network model comprising topology and one or more line parameters.

24. The non-transitory computer-readable medium of claim 20, wherein the operations further comprise synchronizing injections and measurements across nodes using distributed time synchronization, optionally leveraging the stimulus signals themselves.

25. The non-transitory computer-readable medium of claim 20, wherein the operations further comprise performing network model estimation or correction using priors including at least one of geospatial topology, known switch locations, or distance constraints, and accepting hypotheses according to one or more residual metrics.
